(19) United States
(12) Patent Application Publication
(10) Pub. No.: US 2006/0068610 A1
(43) Pub. Date: Mar. 30, 2006

(54) High speed connectors that minimize signal skew and crosstalk

(76) Inventor: Yakov Belopolsky, Harrisburg, PA (US)

Correspondence Address: WOODCOCK WASHBURN LLP, ONE LIBERTY PLACE, 46TH FLOOR, 1650 MARKET STREET, PHILADELPHIA, PA, 19103, US

(21) Appl. No.: 10/953,749

(22) Filed: Sep. 29, 2004

(51) Int. Cl. H05K 1/00

(52) U.S. Cl. 439/65

(57) ABSTRACT

The invention is an electrical connector that minimizes signal skew caused by varying propagation times through different transmission paths within the connector, minimizes crosstalk caused by intermingling electric fields between signal contacts, and maximizes signal density within the connector. The electrical connector may include a plug and receptacle housing, plug contacts, receptacle contacts, and contact plates. The contact plates may include connecting contacts that electrically connect plug contacts to receptacle contacts. The electrical connector minimizes signal skew by maintaining substantially equal-length transmission paths within the connector through varying the lengths and positions of plug and receptacle contacts. The electrical connector minimizes crosstalk by surrounding the connecting contacts with electrical ground by placing the connecting contacts in grooves of the connecting plates. Placing the contacts in such grooves maximizes the signal density of the contact by enabling the contacts to be placed in close proximity with other contacts while minimizing crosstalk.

### FIELD OF THE INVENTION

Generally, the invention relates to electrical connectors. More particularly, the invention relates to electrical connectors that provide high speed, uniform signal propagation, and low interference communications.

### BACKGROUND OF THE INVENTION

Electrical connectors provide signal connections between electronic devices using signal contacts. In many applications of electrical connectors, for example electrical connectors associated with printed wiring boards (PWB), the physical characteristics and close proximity of the signal contacts within the electrical connector may cause degradation of signal integrity. Two causes of signal degradation in electrical connectors are commonly referred to as “skew” and “crosstalk.”

Degradation of signal integrity may be caused by signal propagation delay in one conductor with regard to a related conducted. Signal propagation delay is commonly referred to as “signal skew” or “skew.” One cause of skew in an electrical connector is varying electrical paths within the connector through which signals are conducted. In particular, the electrical path of one conductor will be different than the electrical path of another conductor if the physical length of the conductors in the respective paths are not equal. For example, in differential signal transmission where one signal is carried over two conductors, if the first electrical path for the signal is through a conductor that is physically longer than a conductor used in the second electrical path, the propagation time for each signal through the paths may not be equal. The unequal signal propagation time causes signal skew and degrades signal integrity.

Skew is a particular concern when connecting co-planar devices such as printed wiring boards or printed circuit boards. Often, two right-angle connectors are used when connecting co-planar devices. Each right angle connector may inherently create skew, and therefore, the use of two such connectors in combination intensifies the skew, creating significant degradation of signal integrity. FIG. 1 shows skew associated with prior art, co-planar connectors. FIG. 1 is a side cross section view of prior art, right-angle connectors 173, 174 used to connect two substantially co-planar devices 171, 172. FIG. 1 shows two transmission paths 175, 176 through connectors 173, 174 from device 171 to device 172. In right angle-connector 173, transmission path 175 is longer than transmission path 176, creating signal skew. Likewise, right angle connector 174 suffers from signal skew as well because transmission path 175 is also longer than transmission path 176. Connecting devices 171, 172 using right angle connectors 173, 174 increases the skew that would be present if the devices were connected in a perpendicular manner using just one of the right angle connectors 173, 174.

Another cause of signal degradation is commonly called “crosstalk.” Crosstalk occurs when one signal contact induces electrical interference in another signal contact that is in proximity to it. The electrical interference is caused by intermingling electrical fields between the two contacts. Such interference is a particular problem when signal contacts are closely spaced in electrical connectors. Like skew, crosstalk also may cause significant degradation of signal integrity.

Solutions to the problems of signal skew and crosstalk in an electrical connector are generally in tension. It is well-known in the art of electrical connectors that one way of minimizing skew is to decrease the physical spacing between signal contacts. Decreasing the spacing minimizes skew because the differences in the electrical path—and therefore signal propagation time—are minimized. Decreasing spacing is a welcome solution to skew because, by decreasing spacing, the signal contact density—that is, the number of signal contacts per unit area—of the connector increases.

Minimizing skew by decreasing contact spacing, however, may create or further intensify crosstalk. Crosstalk, as explained, is caused by intermingling electric fields, and therefore placing signal contacts closer together intensifies the intermingling. The solution to the problem of crosstalk is generally to place signal contacts further apart and if possible, to place ground contacts between signal contacts. The solution to crosstalk, therefore, may create or intensify skew and decrease the signal density of the electrical connector.

With electronic device miniaturization and the omnipresent and accelerating need for high speed electronic communications, the reduction of skew and crosstalk are significant goals in electrical connector design. Therefore, there is a need for an electrical connector that minimizes skew and crosstalk while maximizing the signal density of the connector.

### SUMMARY OF THE INVENTION

An electrical connector is disclosed, comprising, in one embodiment, a first and a second contact with a third contact at an angle to and electrically connecting the first and second contacts, wherein an electrical path through the first, second, and third contacts is a first transmission path, and a fourth and a fifth contact with a sixth contact at an angle to and electrically connecting the fourth and fifth contacts, wherein the electrical path through the fourth, fifth, and sixth contacts is a second transmission path, and wherein the first and second transmission paths have a relatively similar signal propagation time. Contacts may be placed in grooves carved out of a metal core associated with electrical ground to minimize intermingling electrical fields between conductors and thus minimize cross talk and maximize signal density of the connector.

In an alternative embodiment, the electrical connector may comprise a first transmission path electrically connecting a first device to a second device, wherein the second device is substantially co-planar with the first device and a second transmission path electrically connecting the first device to the second device, wherein the first and second transmission paths have relatively similar signal propagation times.

In another embodiment, the electrical connector may comprise a plug housing having a plurality of plug contacts, a receptacle housing having a plurality of receptacle contacts, wherein the receptacle contacts are substantially parallel to the plug contacts, a plurality of connecting contacts, wherein each connecting contact electrically connects a plug contact to a receptacle contact to form a transmission path, and wherein each transmission path has a relatively similar signal propagation time as each of the other transmission paths.

### BRIEF DESCRIPTION OF THE DRAWINGS

FIG. 1 is a side cross section view of a prior art method for connecting two substantially co-planar devices;

FIG. 2A is an exploded top perspective view of a plug housing;

FIG. 2B is an exploded top perspective view of a contact base;

FIG. 2C is an exploded top perspective view of a receptacle housing;

FIG. 2D is an exploded top perspective view of and a contact plate;

FIG. 3 is a front cross section view of the plug housing and contact base shown in FIGS. 2A-2B;

FIG. 4A is an exploded top perspective view of a contact;

FIG. 4B is a front, partial cutaway view of a cross section of a plug housing containing the contact shown in FIG. 4A;

FIG. 5 is a front cross section view of an alternative embodiment of a plug housing with a contact base that includes contact plate guiding slots;

FIG. 6 is a side cross section view of a contact plate;

FIG. 7A is a front cross section view of a contact plate for single-end transmission;

FIG. 7B is a front cross section view of a contact plate for differential transmission; and

FIGS. 7C-7E are front cross section views of alternative embodiments of a contact plate.

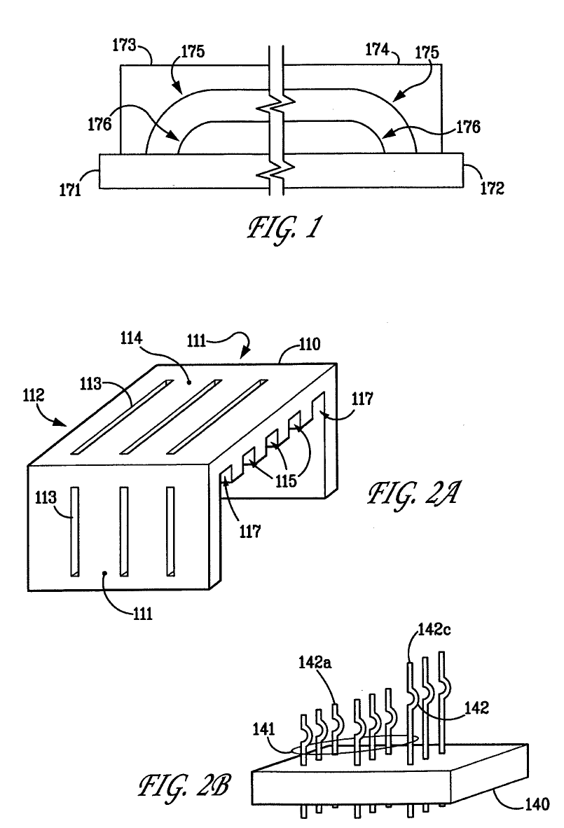

### DETAILED DESCRIPTION OF ILLUSTRATIVE EMBODIMENTS

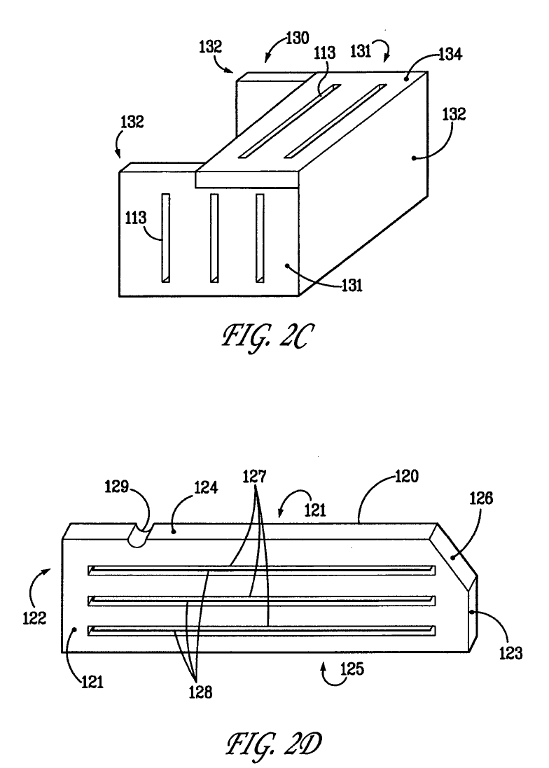

FIG. 2A depicts an example embodiment of a plug housing 110. Plug housing 110 includes side walls 111, a rear wall 112, and a ceiling 114. Plug housing 110 may contain contact plate slots 115 adapted to receive contact plates (not shown). Plug housing 110 may also comprise receptacle housing slots 117 for receiving and facilitating connection with a receptacle housing by allowing the sides of the receptacle housing to slide into the receptacle housing slots 117 of plug housing 110. Plug housing 110 also may include air slits 113 on ceiling 114 or side walls 111 to facilitate thermal release and improve the thermal properties of the electrical connector. Plug housing 110 is shown to be configured to receive three contact plates (not shown) in slots 115 and to receive the receptacle housing sides in receptacle housing slots 117. Plug housing 110, however, may be adapted to receive any number of contact plates. Additionally, a receptacle housing (not shown) may be connected to plug housing 110 with the use of receptacle housing slots 117 or by any other suitable means. Plug housing 110 may be constructed of plastic.

FIG. 2B depicts an example embodiment of a contact base 140 for plug housing 110 and for a receptacle housing (not shown). Contact base 140 may include a plurality of contact rows 141 each comprising a plurality of contacts 142. The contacts 142 in each contact row 141 may be of differing lengths and therefore be disposed to electrically connect with connecting contacts on a contact plate (not shown), discussed below. In one embodiment, the shortest contacts 142a may be located near the rear of contact plate 140 (and therefore near rear wall 112 of plug housing 110 when contact plate 140 is attached to plug housing 110). The longer contacts 141c may be located toward the front of contact plate 140 and therefore toward the front of plug housing 110 when contact base 140 is attached to plug housing 110.

Contacts 142 may protrude through contact base 140 for support and to connect with a device such as a printed wiring board (PWB) or printed circuit board (PCB). Contact base 140 and contacts 142 may be configured to be press-fit into such a device. Contacts 142 are shown to be substantially perpendicular with contact base 140. It should be appreciated, however, that contacts 142 may be at any angle to contact base 140. A contact base 140 may attach to plug housing 110 and a separate contact base 140 may attach to a receptacle housing (not shown) by any suitable means. Contact base 140 may be constructed of plastic or of the same material as the plug housing and be of any suitable thickness.

FIG. 2C depicts an example embodiment of a receptacle housing 130. Receptacle housing 130 includes side walls 131, a rear wall 132, and a ceiling 134. Receptacle housing side walls 131 may extend beyond receptacle housing ceiling 134 and be disposed to slide into receptacle housing slots 117 (FIG. 2A) of plug housing 110 (FIG. 2A). Receptacle housing 130 may contain contact plate slots (not shown) similar to plug housing contact plate slots 115 (FIG. 2A) adapted to receive contact plates 120. Receptacle housing 130 also may include air slits 113 on ceiling 134 or on sides 131 to facilitate thermal release and improve the thermal properties of the electrical connector. Receptacle housing 130 may be constructed of plastic.

As described above, contact base 140 (FIG. 2B) may attach to plug housing 110 (FIG. 2A). A separate contact base 140 may attach to receptacle housing 130 by any suitable means as well. The length of contacts 142 (FIG. 2B) on contact plate 140 attached to receptacle housing 130 would correspond with contacts 142 on contact plate 140 attached to plug housing 110 (FIG. 2A). That is, shorter contacts 142a may be located toward rear wall 112 of plug housing 110 and also toward rear wall 132 of receptacle housing 130. Longer contacts 142c would be located toward the front of plug housing 110 and toward the front of receptacle housing 130.

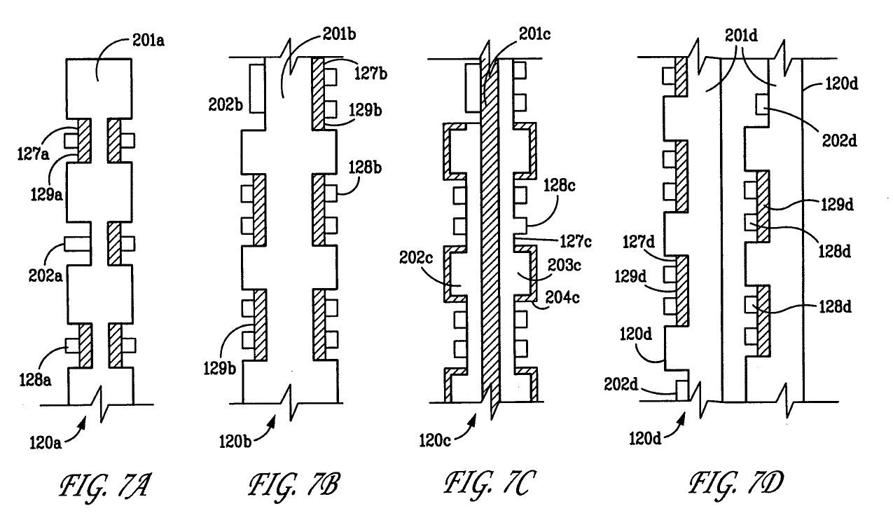

FIG. 2D depicts an example embodiment of a contact plate 120. Contact plate 120 has sides 121, a back 122, a front 123, a top 124 and a bottom 125. The widths of top 124, bottom 125, back 122 and front 123 are substantially uniform and such that contact plate 120 may slide into contact plate slots 115 (FIG. 2A) of plug housing 110 (FIG. 2A) and corresponding slots (not shown) in receptacle housing 130. Contact plate 120 may include grooves 127 along the length of sides 121. As described below in further detail with regard to FIG. 6, grooves 127 may contain connecting contacts 128. Connecting contacts 128 are signal contacts disposed to electrically connect with contacts 142 (FIG. 2B) on contact base 140 when contact base 140 and contact plate 120 are installed in plug housing 110 (FIG. 2A) and receptacle housing 130. Connecting contacts 128 are shown to be parallel with the length of contact plate 120. It should be appreciated, however, that connecting contacts may be in virtually any orientation to electrically connect contacts 142 in plug housing 110 (FIG. 2A) with contacts 142 in receptacle housing 130. Contact plate 120 may also include a retaining dimple 129 that facilitates securing contact plate 120 in plug housing 110 or receptacle housing 130 through mechanical interlock with a beam within the applicable housing (not shown).

In one embodiment, contact plates 120 are fixed in plug housing 110 (FIG. 2A). Receptacle housing 130 is slidably disposed to plug housing 110 and to contact plates 120. Additionally, contact plate 120 may include an angled portion 126 on front 123 to facilitate mating of contact plate 120 with receptacle housing 130. Contact plate 120, however, may be fixed in receptacle housing 130, and plug housing 110 may be slidably disposed to receptacle housing 130 and contact plates 120. Alternatively, contact plates 120 may be slidably disposed towards and remain unfixed in both plug housing 110 (FIG. 2A) and receptacle housing 130.

In one embodiment, contact base 140 (FIG. 2B) may be attached to plug housing 110 (FIG. 2A) and a separate contact base 140 (FIG. 2B) may be attached to receptacle housing 130. Contact plates 120 may be inserted into contact plate slots 115 of plug housing 110 (FIG. 2A) and fixed within plug housing 110 (FIG. 2A) through operation of a retaining bar (not shown) engaging retaining dimple 129 of contact plates 120. Receptacle housing 130 with contact plate 140 (FIG. 2B) may then be connected to plug housing 110 (FIG. 2A) by sliding receptacle housing sides 131 into receptacle housing slots 117 of plug housing 110 until contacts 142 on contact base 140 of receptacle housing 130 contact with the corresponding connecting contacts 128 on contact plate 120. The connector could then be, for example, press-fit onto or otherwise connected to a device such as a PWB or PCB.

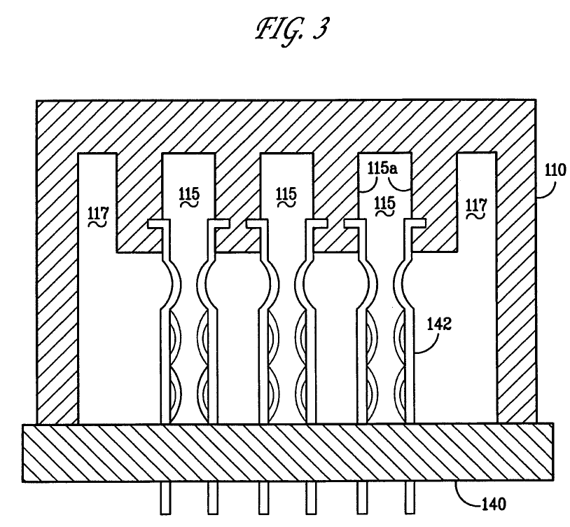

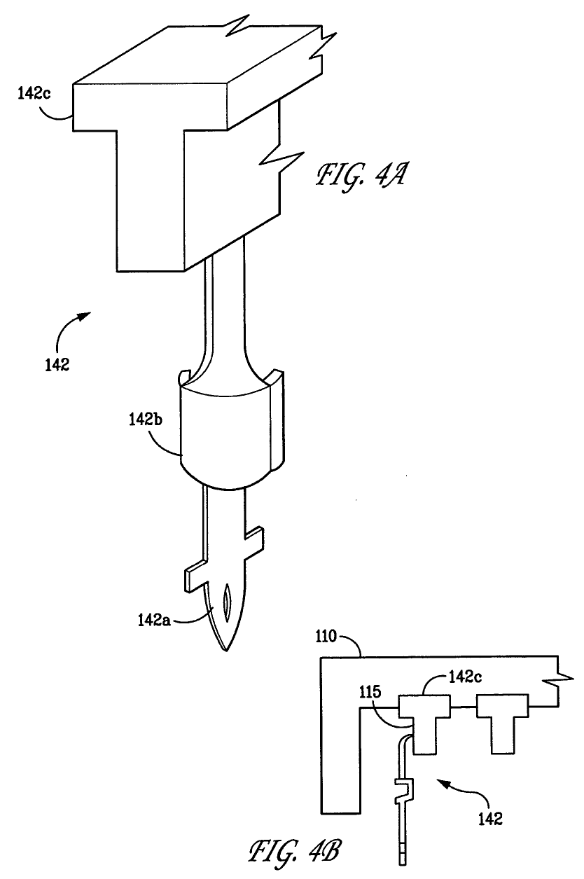

FIG. 3 is a front, sectional view of an example embodiment of plug housing 110 with contact plate 140 attached in accordance with the invention. Plug housing 110 may include contact plate slots 115 and receptacle housing slots 117. Contacts 142 may protrude through contact plate 140 for support and to facilitate connection to a device. In one embodiment, contacts 142 may be supported by sides 115a of contact plate slots 115. This support is shown in greater detail in FIG. 4.

FIG. 4A depicts an example embodiment of contact 142 in accordance with the invention. Contact 142 may have a tip 142a protruding through contact base 140 (not shown) and electrically connecting with a device. Contact 142 may also have a contact surface 142b for facilitating contact with connecting contact 128 (FIG. 2D) on contact plate 120 (FIG. 2D). At the end opposite tip 142a, the contact may be formed as part of an overmolded wafer 142c. Overmolded wafer 142c may be constructed of plastic or of the same material as plug or receptacle housings 110, 130.

FIG. 4B is a cut-away view of a front, cross section of an example embodiment of plug housing 110 or receptacle housing 130 in accordance with the invention. FIG. 4B shows an overmolded wafer 142c with contact 142 formed as part of it. Overmolded wafer 142c may be attached or formed as part of plug housing 110 or receptacle housing 130. More specifically, overmolded wafer 142c may be formed as part of contact plate slot 115 of plug housing 110 or of a corresponding slot in receptacle housing 130.

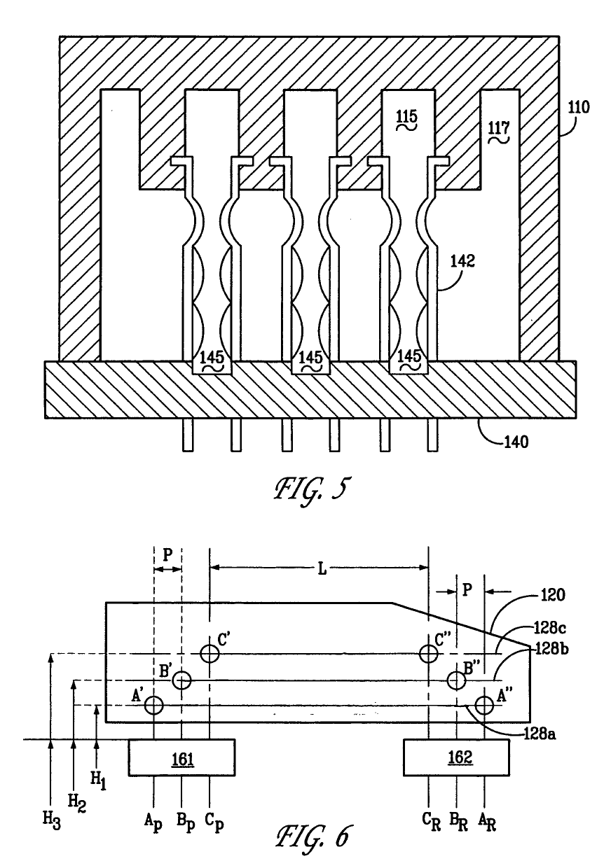

FIG. 5 is a front, sectional view of an alternative example embodiment of a plug housing 110 and contact plate 140. FIG. 5 is described in relation to plug housing 110 but the elements of FIG. 5 may be present in receptacle housing 130 as well. Plug housing 110 and contact plate 140 include the elements as shown and described with regard to plug housing 110 and contact plate 140 of FIG. 3 and therefore such elements are not further described with regard to FIG. 5. In addition, contact base 140 may include contact plate guiding slots 145. Contact plate guiding slots 145 may facilitate guiding and supporting contact plates 120 (not shown) in plug housing 110 or receptacle housing 130 (FIG. 2D).

It should be noted that, while FIGS. 3-5 describe example embodiments with regard to plug housing 110, the descriptions may be equally applicable to receptacle housing 130 (FIG. 2C). Consistent with the invention, receptacle housing 130 may have slots for receiving plug housing sides 111 (FIG. 2A) if configured similar to receptacle housing sides 131 (FIG. 2C) of housing receptacle 130 (FIG. 2C).

FIG. 6 illustrates maintaining substantially equal transmission paths through the electrical connector, thereby minimizing skew. FIG. 6 depicts a side view of a cross section of an example embodiment of contact plate 120 in accordance with the invention. More specifically, FIG. 6 shows the relative location of contact plate 120 when the electrical connector is connecting two substantially co-planar devices 161, 162. Co-planar devices 161, 162 may be PWBs or any other electronic device. It should be noted that the electrical connector also may be used in connecting non-co-planar devices as well. FIG. 6 represents just one of many ways in which the electrical connector may be constructed with transmission paths of substantially equal length in accordance with the invention. FIG. 6 does not show plug housing 110 (FIG. 2A) or receptacle housing 130 (FIG. 2C) for the sake of clarity.

In FIG. 6, contacts A_{P}, A_{R}, B_{P}, B_{R}, C_{P}, and C_{R} represent contacts 142 (FIG. 2B) on contact plate 140 (FIG. 2B). Points A¹, A^{11,} B¹, B^{11,} C¹, and C¹¹ represent the locations where respective contacts A_{P}, A_{R}, B_{P}, B_{R}, C_{P}, and C_{R} electrically connect with connecting contacts 128 of contact plate 120 when the electrical connector is assembled. While connecting contacts 128 are shown to be at essentially a right angle to contacts 142, it should be appreciated that connecting contacts 128 may be at any angle to contacts 142. Points A¹ and A¹¹ are located at a height H₁ from, respectively, devices 161, 162. Points B¹ and B¹¹ are located at a height H₂ from, respectively, devices 161, 162. Points C¹ and C¹¹ are located at a height H₃ from, respectively, devices 161, 162. The horizontal spacing between contacts A_{P} and B_{P}, between B_{P} and C_{P}, between A_{R} and B_{R}, and between B_{R} and C_{R} is equal to a length p.

Length p is equal to the length H₁ of each of contacts A_{P} and A_{R}. The length H₂ of each of contacts B_{P} and B_{R} is equal to two times length H₁. The length H₃ of each of contacts C_{P} and C_{R} is equal to three times length H₁. The length L between contacts C_{P} and C_{R} is equal to the length of connecting contact 128c that connects C_{P} and C_{R}. The following mathematical equations show how, in one example embodiment of the invention, the three transmission path lengths A_{P}, A_{R}, B_{P}, B_{R}, and C_{P}, C_{R} are equal:
A_{P}, A_{R}=H₁+2p+L+2p+H₁=2H₁+4p+L=2H₁+4H₁+L=6H₁+L
B_{P}, B_{R}=H₂+p+L+p+H₂=2H₂+2p+L=2H₂+2H₁+L=4H₁+2H₁+L=6H₁+L
C_{P}, C_{R}=H₃+L+H₃=2H₃+L=6H₁+L

Therefore, the transmission path from device 161 through contact A¹, connecting contact 128a, and contact A¹¹ to device 162 is equal in length to the transmission path from device 161 through contact B¹, connecting contact 128b, and contact B¹¹ to device 162. Additionally, the transmission path from device 161 through contact C¹, connecting contact 122c, and contact C¹¹ to device 162 is substantially equal to each of the other two transmission paths. Because the transmission paths through the connector are of equal lengths, the electrical connector may be used to connect two substantially co-planar devices 161, 162 while minimizing skew. Of course, in other embodiments of the invention, the above mathematical equations may not be applicable. The relationship between the lengths of and the spacing between contacts 142 may be altered while maintaining equivalent transmission paths. Additionally, in alternative embodiments, the contacts may be straight as depicted in FIG. 6, bent, curved or of any other appropriate shape.

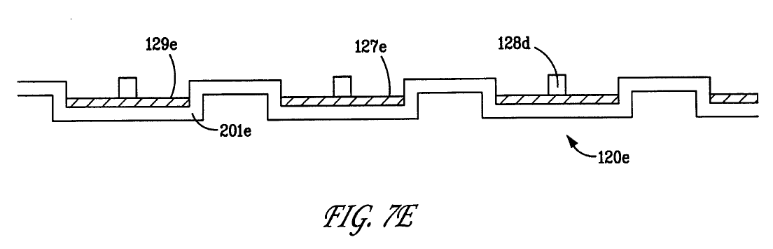

FIG. 7 depicts cross section end views of example embodiments of contact plates 120 (FIG. 2D) in accordance with the invention. FIG. 7 shows various ways to reduce or minimize crosstalk between signal contacts in the electrical connector in accordance with the invention.

FIG. 7A depicts an embodiment of a contact plate 120a to be used to minimize crosstalk in accordance with the invention. Contact plate 120a may include a metal core 201a that serves as an electrical ground. The metal core may contain grooves 127a that are covered by a dielectric material 129a, such as oxide or polyimide film. Connecting contacts 128a may be affixed to dielectric layer 129a. Additionally, contact plate 120a may have a ground contact 202a affixed to the core 201a if deemed necessary. When affixed to dielectric layer 129a in grooves 127a, connecting contacts 128a are surrounded by electrical ground of metal core 201a. Surrounding connecting contacts 128a with ground minimizes cross talk in the connector by preventing electric fields that surround connecting contacts 128a from intermingling. Contact plate 120a may be used in connectors using single-ended transmission.

FIG. 7B depicts an example embodiment of contact plate 120b that may be used in an electrical connector. Contact plate 120b is similar to contact plate 120a (FIG. 7A) except that contact plate 120b may be used for differential transmission of signals through the electrical connector. Like contact 120a (FIG. 7A), contact 120b may include a metal core 201b, grooves 127b that are covered by a dielectric material 129b, and ground contacts 202b attached to metal core 201b. Unlike contact plate 120a, however, contact plate 120b includes two connecting contacts 128b in each groove 127b. The two connecting contacts 128b in each groove 127b carry the transmission signal.

FIG. 7C depicts an alternative embodiment of contact plate 120c for use in an electrical connector. Contact plate 120c has a metal core 201c with a dielectric layer 203c affixed to metal core 201c. Dielectric layer 203c may be constructed of plastic. Grooves 127c are formed in dielectric layer 203c and connecting contacts 128c are placed in grooves 127c on dielectric layer 203c. The areas 204c around the connecting contacts may be coated with metal or “metallized.” Additionally a ground contact 202c may be placed on metal core 201c. Contact plate 120c as shown may be used in differential transmission in electrical conductors, but those skilled in the art of electrical connectors would recognize that contact plate 120c could be adapted for use with single-ended transmissions as well.

FIG. 7D is an alternative embodiment of contact plate 120d for use in an electrical connector. In FIG. 7D, two contact plates 120d are shown. As with contact plate 120b (FIG. 7B), contact plates 120d may include a metal core 201d, grooves 127d that are covered by a dielectric material 129d, and ground contacts 202d attached to metal core 201d. Additionally, grooves 127d may each have two connecting contacts 128d for differential transmission. Contrary to contact plate 120b, contact plates 120d may have connecting contacts on only one side. Contact plates 120d may be closely spaced together in plug housing 110 (FIG. 2A) and receptacle housing 130 (FIG. 2C) so that the metal core 201d of one contact plate 120d is in close proximity to connecting contacts 128d of an adjacent contact plate 120d. Similar to placing connecting contacts 128d in grooves 127d surrounded by metal core 201d, maintaining a close proximity between core 201d of one contact plate 120d and the connecting contacts 128d of a second contact plate 120d decreases crosstalk between connecting contacts 128d.

FIG. 7E is an alternative embodiment of contact plates 120e for use in an electrical connector. In this embodiment, the metal core may be bent or stamped to create grooves 127e, which may be a less expensive way to manufacture contact blades to reduce crosstalk according to the invention.

It is to be understood that even though numerous characteristics and advantages of the present invention have been set forth in the foregoing description, the disclosure is illustrative only and changes may be made in detail within the principles of the invention to the full extent indicated by the broad general meaning of the terms in which appended claims are expressed. For example, the electrical connector has been described in conjunction with connecting two substantially co-planar devices such as PWBs. It should be recognized, however, that the invention may be used in connecting other devices including those that are not co-planar.

1. An electrical connector, comprising:
a first and a second contact;
a third contact electrically connecting the first and second contacts, wherein the third contact is at an angle to the first and second contacts, and wherein an electrical path through the first, second, and third contacts is a first transmission path;
a fourth and a fifth contact;
a sixth contact electrically connecting the fourth and fifth contacts, wherein the sixth contact is at an angle to the fourth and fifth contacts, wherein an electrical path through the fourth, fifth, and sixth contacts is a second transmission path, wherein a spacing between the first and second contacts is different than a spacing between the fourth and fifth contacts, and wherein the first and second transmission paths have a relatively similar signal propagation time.

2. The electrical connector of claim 1, wherein the lengths of each of the first, second, fourth, and fifth contacts are proportional.

3. The electrical connector of claim 1, wherein a spacing between the first and fourth contacts is proportional to a spacing between the second and fifth contacts.

4. The electrical connector of claim 3, wherein the lengths of each of the first, second, fourth, and fifth contacts are proportional.

5. The electrical connector of claim 1, wherein the spacing between the first and fourth contacts is approximately equal to the spacing between the second and fifth contacts, and wherein the length of each of the fourth and fifth contacts is approximately twice the length, respectively, of the first and second contacts.

6. The electrical connector of claim 5, wherein the length of each of the first and second contacts is equal to the spacing between the first and fourth contact.

7. The electrical connector of claim 1, wherein the first contact is substantially parallel to the second contact, and wherein the fourth contact is substantially parallel to the fifth contact.

8. The electrical connector of claim 1, wherein the third contact is substantially perpendicular to the first and second contacts, and wherein sixth contact is substantially perpendicular to the fourth and fifth contacts.

9. The electrical connector of claim 1, wherein the third and sixth contacts form an arc.

10. The electrical connector of claim 1, wherein the first and fourth contacts electrically connect to a first device, and wherein the second and fifth contacts electrically connect to a second device.

11. The electrical connector of claim 10, wherein the first and fourth contacts are substantially perpendicular to the devices, and wherein the second and fifth contacts are substantially perpendicular to the second device.

12. The electrical connector of claim 10, wherein the third and sixth contacts are substantially parallel to the first and second devices.

13. The electrical connector of claim 10, wherein the devices are printed wiring boards.

14. The electrical connector of claim 10, wherein the first device is substantially co-planar with the second device.

15. The electrical connector of claim 1, further comprising:
a seventh and an eighth contact, wherein the seventh contact is substantially parallel to the eighth contact;
a ninth contact electrically connecting the seventh and eighth contacts, wherein an electrical path through the seventh, eighth, and ninth contacts is a third transmission path, and wherein the third transmission path has a relatively similar signal propagation time as each of the first and second transmission path.

16. The electrical connector of claim 15 wherein, the lengths of each of the first, second, fourth, fifth, seventh, and eighth contacts are proportional.

17. The electrical connector of claim 15 wherein, the spacing between each of the first and fourth, the fourth and seventh, the second and fifth, and the fifth and eighth contacts are proportional.

18. The electrical connector of claim 17, wherein the height of each of the fourth and fifth contacts is approximately twice the height of each of the first and second contacts, and wherein the height of each of the seventh and eighth contacts is approximately three times the height of each of the first and second contacts.

19. The electrical connector of claim 18, wherein the height of each of the first and second contacts is equal to the spacing between the first and fourth contacts.

20. An electrical connector, comprising:
a first transmission path electrically connecting a first device to a second device, wherein the second device is substantially co-planar with the first device, and wherein the first transmission path comprises a contact having a first length; and
a second transmission path electrically connecting the first device to the second device, wherein the second transmission path comprises a contact having a second length different from the first length, and wherein the first and second transmission paths have relatively similar signal propagation times.

21. The electrical connector of claim 20, wherein the first transmission path comprises:
a first contact electrically connected to the first device;
a second contact electrically connected to the second device; and
a third contact electrically connecting the first and second contacts.

22. The electrical connector of claim 20, wherein the second transmission path comprises:
a fourth contact electrically connected to the first device;
a fifth contact electrically connected to the second device; and
a sixth contact electrically connecting the fourth and fifth contacts.

23. The electrical connector of claim 20, further comprising a third transmission path, wherein the third transmission path comprises,
a seventh contact electrically connected to the first device,
an eighth contact electrically connected to the second device, and
a ninth contact electrically connecting the seventh and eighth contacts.

24. The electrical connector of claim 20, wherein the first and second devices are printed wiring boards.

25. The electrical connector of claim 20, wherein the first and second devices are printed circuit boards.

26. An electrical connector comprising:
a plug housing having a plurality of plug contacts;
a receptacle housing connected to the plug housing having a plurality of receptacle contacts, wherein the receptacle contacts are substantially parallel to the plug contacts; and
a plurality of connecting contacts, wherein each connecting contact electrically connects a plug contact to a receptacle contact to form a transmission path, wherein each transmission path has a relatively similar signal propagation time as each of the other transmission paths, and wherein a length of a first connecting contact of the plurality of connecting contacts is different from a length of a second connecting contact of the plurality of connecting contacts.

27. The electrical connector of claim 26, wherein the connecting contacts are located on a contact plate, wherein the contact plate is secured in the plug housing, and wherein the contact plate is slidably disposed toward the receptacle housing.

28. The electrical connector of claim 27, further comprising:
a plug contact base having holding slots that facilitate holding the contact plates in position in the plug housing; and
a receptacle contact base having guiding slots, wherein each guiding slot guides a contact plate as the receptacle housing is connected to the plug housing.

29. The electrical connector of claim 27, wherein the contact plate comprises:
a metal core;
a plurality of grooves in the metal core;
a layer of dielectric material within each of the plurality of grooves; and
a connecting contact on the dielectric layer within each of the plurality of grooves.

30. The electrical connector of claim 29, wherein the contact plate further comprises one or more ground contacts in contact with the metal core.

31. The electrical connector of claim 27, wherein the contact plate comprises:
a metal core;
a polymer isolator layer adjacent to each side of the metal core;
a plurality of grooves in the polymer isolator layer;
a connecting contact within each of the plurality of grooves, wherein the polymer isolator layer is metalized around the connecting contacts.

32. The electrical connector of claim 31, wherein the contact plate further comprises one or more ground contacts in contact with the metal core.

33. The electrical connector of claim 27, wherein the contact plate is a printed wiring board.

34. The electrical connector of claim 26, wherein the plug contacts and receptacle contacts protrude through and are supported by, respectively, a plug contact base and a receptacle contact base, and wherein the plug contacts and receptacle contacts electrically connect with, respectively, a first device and a second device.

35. The electrical connector of claim 26, wherein the first and second devices are printed wiring boards.

36. The electrical connector of claim 26, wherein the electrical connector carries at least one of single-end and differential transmission signals.

37. The electrical connector of claim 26, wherein the connector is a back-plane connector.

38. The electrical connector of claim 26, wherein the contact plate comprises a retaining dimple to facilitate securing the contact plate within the plug housing.

39. The electrical connector of claim 26, wherein the plug and receptacle contacts are part of an over-molded wafer.

40. The electrical connector of claim 39, wherein the wafer is part of at least one of the plug and receptacle housing.

41. The electrical connector of claim 26, wherein the plug housing further comprises slots for receiving a wall of the receptacle housing the receptacle housing is attached to the plug housing.

42. A method of connecting a first device and a second device, wherein the devices are substantially co-planar board, the method comprising:
connecting a first contact of a first length to the first board;
connecting a second contact of a second length to the second board;
connecting the first and second contacts with a third contact of a third length that is angled with respect to the first and second contacts;
connecting a fourth contact of a fourth length to the first board, wherein the spacing between the first contact and the fourth contact is a first spacing;
connecting a fifth contact of a fifth length to the second board, wherein the spacing between the second contact and the fifth contact is a second spacing; and
connecting the fourth and fifth contacts with a sixth contact of a sixth length that is angled with respect to the fourth and fifth contacts, wherein a sum of the fourth, fifth, and sixth lengths is substantially similar to a sum of the first, second, and third lengths, and wherein the third length is different from the sixth length.

43. The method of claim 42, wherein each of the fourth and fifth lengths is proportional to at least one of the first and second lengths.

44. The method of claim 42, wherein the first spacing is proportion to the second spacing.
